(19) United States
(12) Patent Application Publication
(10) Pub. No.: US 2008/0305408 A1
(43) Pub. Date: Dec. 11, 2008

(54) APERTURE MASK, MANUFACTURING METHOD THEREOF, CHARGE BEAM LITHOGRAPHY APPARATUS, AND CHARGE BEAM LITHOGRAPHY METHOD

(75) Inventor: Keizo HIROSE, Sagamihara-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo-to (JP)

(21) Appl. No.: 11/758,898

(22) Filed: Jun. 6, 2007

(51) Int. Cl. G03F 1/00; G03C 5/00

(52) U.S. Cl. 430/5; 430/296

(57) ABSTRACT

An aperture mask according to an embodiment of the present invention is an aperture mask for charged beam lithography, and includes: a mask substrate having a first semiconductor layer, an insulating film formed on the first semiconductor layer, and a second semiconductor layer formed on the insulating film, and provided with an aperture which penetrates the first semiconductor layer, the insulating film, and the second semiconductor layer; and a conductive layer which coats a surface of the mask substrate and a side wall surface of the aperture formed in the mask substrate, and which coats an exposed surface of the insulating film exposed to the side wall surface of the aperture.

### BACKGROUND OF THE INVENTION

1. Field of the Invention

The present invention relates to an aperture mask, a manufacturing method thereof, a charged beam lithography apparatus, and a charged beam lithography method.

2. Background Art

As a technique for patterning an integrated circuit and the like, a laser beam lithography scheme using a laser beam is currently being widely used. On the other hand, an electron beam lithography scheme using an electron beam has appeared recently due to the need for super fine patterning (Japanese Patent Laid-Open No. 2005-183530, Japanese Patent Laid-Open No. 2003-297715, Japanese Patent Laid-Open No. 2003-163149 and the like). The electron beam lithography scheme is classified into a type using an aperture mask (stencil mask) and a type not using any aperture mask. Specific examples of the electron beam lithography scheme using an aperture mask include a VSB scheme (variable shaped beam scheme), a CP scheme (character projection scheme), and a collective projection scheme (Japanese Patent Laid-Open No. H08-22941, Japanese Patent Laid-Open No. H09-205058, “I. Amemiya et al., Photomask and X-Ray Mask Technology IV, vol. 3096, p. 251, 1997 (SPIE)” and the like). Each of the VSB scheme and the CP scheme usually uses a first aperture mask for shaping a rectangular beam and a second aperture mask for shaping a patterning beam.

According to the electron beam lithography scheme using an aperture mask, an electron beam is irradiated onto the aperture mask, and the electron beam is shaped by the aperture mask. Electrons which have been shot into the aperture mask by irradiation of the electron beam, remain on the surface of an insulating film which constitutes the aperture mask, and have an adverse effect on the track of a subsequent electron beam which passes through the aperture mask. As a technique for preventing this, there is a known technique such as sputtering the aperture mask to coat it with a conductive layer, when manufacturing the aperture mask. This allows electrons shot into the aperture mask to be mostly removed.

However, when sputtering the aperture mask, the surface of the aperture mask is easily coated, whereas the side wall surface of the aperture formed in the aperture mask is hard to be coated. Therefore, electrons which have been shot into the aperture mask by irradiation of an electron beam and which have remained slightly on the surface of the insulating film that constitutes the aperture mask, have an adverse effect, from the vicinity of the exposed surface of the insulating film exposed to the side wall surface of the aperture, on the track of a subsequent electron beam which passes through the vicinity of the side wall surface of the aperture. This effect is often insignificant when a highly accelerated electron beam on the order of 50 to 100 keV are used, but the effect often cannot be ignored when a lowly accelerated electron beam on the order of 1 to 5 keV are used.

### SUMMARY OF THE INVENTION

The present invention relates to charged beam lithography using an aperture mask for the charged beam lithography, and it is an object of the present invention to prevent charges shot into the aperture mask from having an adverse effect on the track of a subsequent charged beam which passes through the aperture mask.

An aspect of the present invention is an aperture mask for charged beam lithography, the aperture mask including: a mask substrate having a first semiconductor layer, an insulating film formed on the first semiconductor layer, and a second semiconductor layer formed on the insulating film, and provided with an aperture which penetrates the first semiconductor layer, the insulating film, and the second semiconductor layer; and a conductive layer which coats a surface of the mask substrate and a side wall surface of the aperture formed in the mask substrate, and which coats an exposed surface of the insulating film exposed to the side wall surface of the aperture.

Another aspect of the present invention is an aperture mask for charged beam lithography, the aperture mask including: a mask substrate having an insulating film, and provided with an aperture which penetrates the insulating film; and a conductive layer which coats an exposed surface of the insulating film exposed to a side wall surface of the aperture.

Another aspect of the present invention is a method of manufacturing an aperture mask for charged beam lithography, the method including: forming, in a mask substrate having a first semiconductor layer, an insulating film formed on the first semiconductor layer, and a second semiconductor layer formed on the insulating film, an aperture which penetrates the first semiconductor layer, the insulating film, and the second semiconductor layer; and forming a conductive layer which coats a surface of the mask substrate and a side wall surface of the aperture formed in the mask substrate, and which coats an exposed surface of the insulating film exposed to the side wall surface of the aperture.

Another aspect of the present invention is a method of manufacturing an aperture mask for charged beam lithography, the method including: forming, in a mask substrate having an insulating film, an aperture which penetrates the insulating film; and forming a conductive layer which coats an exposed surface of the insulating film exposed to a side wall surface of the aperture.

Another aspect of the present invention is a charged beam lithography apparatus including: the above-described aperture mask or an aperture mask manufactured by the above-described method.

Another aspect of the present invention is a charged beam lithography method including: performing charged beam lithography using the above-described aperture mask or an aperture mask manufactured by the above-described method.

### BRIEF DESCRIPTION OF THE DRAWINGS

FIG. 1 is a cross-sectional side view of an aperture mask for electron beam lithography;

FIG. 2 is an enlarged cross-sectional side view of the aperture mask for electron beam lithography;

FIG. 3 is a top view of a first aperture mask for a VSB scheme;

FIG. 4 is a top view of a second aperture mask for a VSB scheme;

FIG. 5 is an enlarged cross-sectional side view of an embodiment of an aperture mask provided with a conductive layer;

FIG. 6 is an enlarged cross-sectional side view of a comparative example of an aperture mask provided with a conductive layer;

FIGS. 7A to 7F are cross-sectional side views regarding a manufacturing method of the aperture mask in FIG. 1; and

FIG. 8 shows an electron beam lithography apparatus.

### DESCRIPTION OF THE EMBODIMENTS

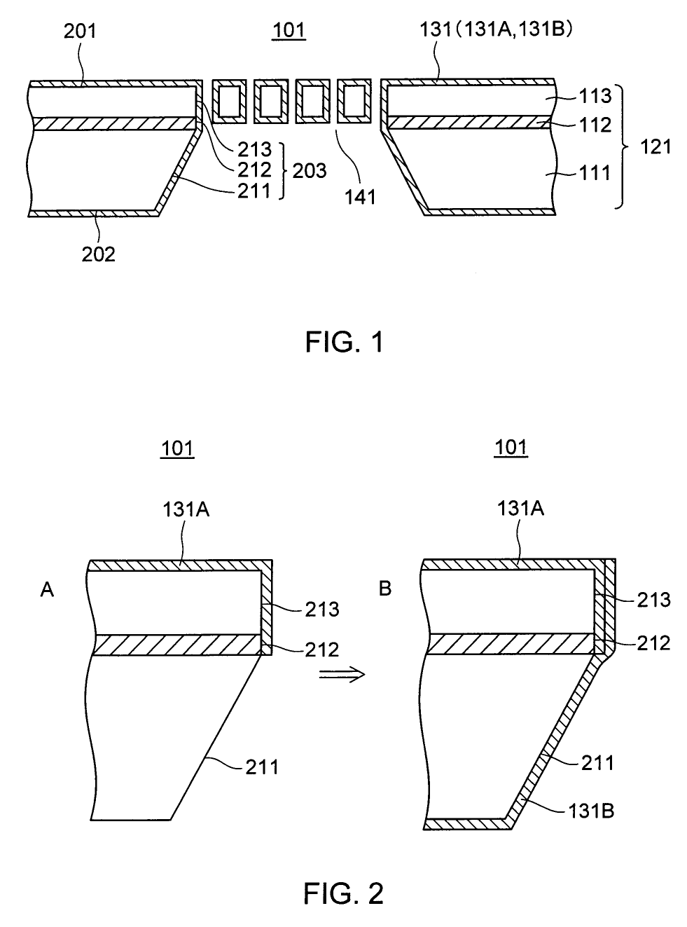

FIG. 1 is a cross-sectional side view of an aperture mask 101 for electron beam lithography. The aperture mask 101 shown in FIG. 1 may be an aperture mask for a VSB scheme, for a CP scheme, or for a collective projection scheme. The aperture mask 101 shown in FIG. 1 may be a first aperture mask for shaping a rectangular beam or a second aperture mask for shaping a patterning beam. The aperture mask 101 shown in FIG. 1 corresponds to a specific example of an aperture mask for charged beam lithography.

The aperture mask 101 in FIG. 1 includes an SOI (Semiconductor On Insulator) substrate 121 having a semiconductor substrate 111, an insulating film 112, and a semiconductor layer 113, and a conductive layer 131. The aperture mask 101 (SOI substrate 121) is provided with an aperture 141 which penetrates the semiconductor substrate 111, the insulating film 112, and the semiconductor layer 113. The semiconductor substrate 111 corresponds to a specific example of a first semiconductor layer of the present invention. The insulating film 112 corresponds to a specific example of an insulating film of the present invention. The semiconductor layer 113 corresponds to a specific example of a second semiconductor layer of the present invention. The SOI substrate 121 corresponds to a specific example of a mask substrate of the present invention. The conductive layer 131 corresponds to a specific example of a conductive layer of the present invention. The aperture 141 corresponds to a specific example of an aperture of the present invention.

The semiconductor substrate 111 is a silicon substrate here. The insulating film 112 is formed on the semiconductor substrate 111. The insulating film 112 is a silicon oxide film here, but may also be a silicon nitride film. The semiconductor layer 113 is formed on the insulating film 112. The semiconductor layer 113 is a silicon film here. The SOI substrate 121 is manufactured by forming the insulating film 112 and the semiconductor layer 113 on the semiconductor substrate 111 here, but the SOI substrate 121 may also be manufactured by bonding a semiconductor substrate and another semiconductor substrate together via an insulating film. The SOI substrate 121 has the semiconductor substrate 111, the insulating film 112, and the semiconductor layer 113 here, but it may also be provided with an additional layer.

The conductive layer 131 is a tungsten film here, but it may also be an iridium film, a platinum film, or a titanium film. The material for forming the conductive layer 131 is preferably a metallic material whose electric resistance is hardly changed by oxidation. This is because when the material for forming the conductive layer 131 is a metallic material whose electric resistance is drastically changed by oxidation, the performance of the conductive layer 131 for removing shot-in electrons is weakened by oxidation of the conductive layer 131 with long-term use of the aperture mask 101. The aperture mask 101 is used in a condition that the conductive layer 131 is connected to ground potential. Electrons which are shot into the aperture mask 101 are removed from the conductive layer 131 to the ground.

The conductive layer 131 is formed by a metal CVD (chemical vapor deposition) method here. When the conductive layer 131 is formed by a sputtering method as in a conventional case, the surface of the SOI substrate 121 can be easily coated, whereas the side wall surface of the aperture 141 formed in the SOI substrate 121 is hard to be coated. On the contrary, when the conductive layer 131 is formed by a metal CVD method, not only the surface of the SOI substrate 121 is preferably coated, but also the side wall surface of the aperture 141 formed in the SOI substrate 121 is preferably coated. Therefore, the exposed surface of the insulating film 112 which is exposed to the side wall surface of the aperture 141 is coated with the conductive layer 131. As a method of forming the conductive layer 131, any method other than the metal CVD method capable of preferably coating the side wall surface of the aperture 141 may also be adopted. The metal CVD method has an advantage over the sputtering method and the like that a layer to be formed becomes flat, and also has an advantage over a plating method and the like that no seed is required to form a layer. When seed processing is performed, a charge source which may have an adverse effect on the track of an electron beam is generated.

With regard to the surface of the SOI substrate 121 (substrate surface), an upper surface 201 corresponds to the surface of the semiconductor layer 113, and a lower surface 202 corresponds to the surface of the semiconductor substrate 111. The conductive layer 131 coats the upper surface 201 of the SOI substrate 121, the lower surface 202 of the SOI substrate 121, and a side wall surface 203 of the aperture 141 formed in the SOI substrate 121. The side wall surface 203 of the aperture 141 includes an exposed surface 211 of the semiconductor substrate 111, an exposed surface 212 of the insulating film 112, and an exposed surface 213 of the semiconductor layer 113. The conductive layer 131 coats these exposed surfaces 211, 212, and 213.

Such a conductive layer 131 is realized by performing a process of depositing the conductive layer 131 twice. That is, first as shown in FIG. 2A, a first conductive layer 131A, which coats the upper surface 201 of the SOI substrate 121 and the side wall surface 203 of the aperture 141, is deposited by metal CVD from the upside of the SOI substrate 121, and then as shown in FIG. 2B, a second conductive layer 131B, which coats the lower surface 202 of the SOI substrate 121 and the side wall surface 203 of the aperture 141, is deposited by metal CVD from the underside of the SOI substrate 121. The conductive layer 131 becomes a 2-layer conductive layer including the conductive layer 131A and the conductive layer 131B. The material for forming the conductive layer 131A and the material for forming the conductive layer 131B are the same material here, but may also be different materials. Here, metal CVD from the upside of the SOI substrate 121 is performed, followed by metal CVD from the underside of the SOI substrate 121, but metal CVD from the underside of the SOI substrate 121 may be performed, followed by metal CVD from the upside of the SOI substrate 121.

On the side wall surface 203 of the aperture 141, the first conductive layer 131A and the second conductive layer 131B are deposited. Therefore, the size of the aperture 141 is reduced by the thicknesses of the conductive layer 131A and the conductive layer 131B. Therefore, the design value of the size of the aperture of the SOI substrate 121 is set to be greater than the design value of the size of the aperture of the aperture mask 101, by the thicknesses of the conductive layer 131A and the conductive layer 131B. Of course, the difference of these design values in a region where one of the conductive layer 131A and the conductive layer 131B is deposited, is different from the difference of these design values in a region where both of the conductive layer 131A and the conductive layer 131B are deposited. In FIG. 2, the former region is the exposed surface 211 of the semiconductor substrate 111, and the latter region is the exposed surface 212 of the insulating film 112 and the exposed surface 213 of the semiconductor layer 113.

Hereinafter, the functions of the conductive layer 131 will be explained in detail.

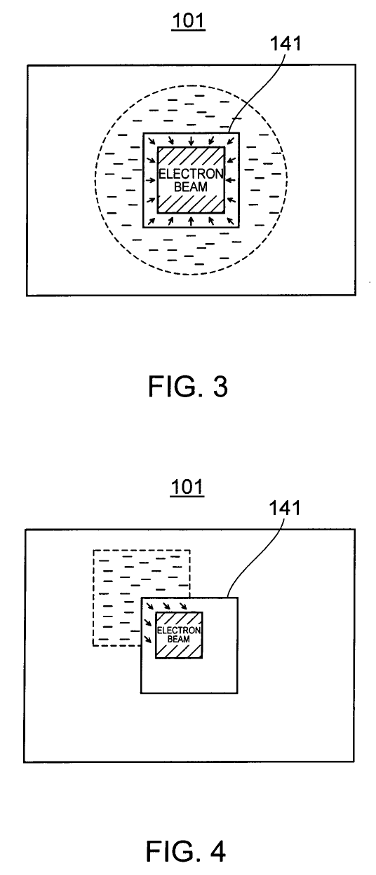

FIG. 3 and FIG. 4 show top views of a first aperture mask 101 and a second aperture mask 101 for a VSB scheme. However, it is supposed that each of the first and second aperture masks 101 in FIG. 3 and FIG. 4 is not provided with the conductive layer 131.

Electrons which have been shot into the aperture masks 101 in FIG. 3 and FIG. 4 by irradiation of an electron beam, remain on the surfaces of insulating films which constitute the aperture masks 101, as shown with “minus signs” in FIG. 3 and FIG. 4, and have an adverse effect on the track of a subsequent electron beam which passes through the aperture masks 101. More specifically, as shown with “arrows” in FIG. 3 and FIG. 4, Coulomb repulsive force acts between the remaining electrons and the subsequent electron beam, so that the track of the subsequent electron beam is bent.

However, the aperture mask 101 in FIG. 1 is provided with the conductive layer 131, as shown in FIG. 1, on the surfaces 201 and 202 and the side wall surface 203 of the aperture mask 101. Therefore, electrons shot into the aperture mask 101 are mostly removed from the conductive layer 131 to the ground. In this way, the aperture mask 101 in FIG. 1 can prevent electrons shot into the aperture mask 101 from having an adverse effect on the track of a subsequent electron beam which passes through the aperture mask 101.

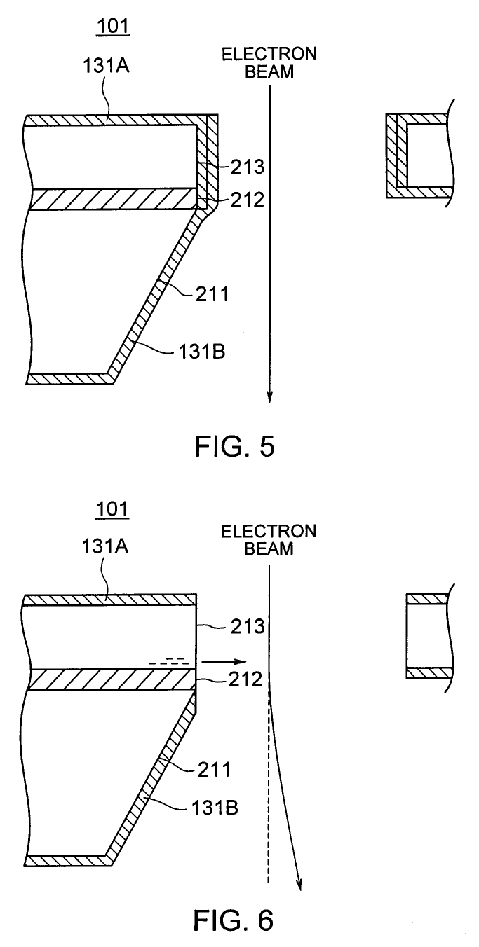

FIG. 5 and FIG. 6 are enlarged cross-sectional side views of an embodiment and a comparative example of aperture masks 101 provided with conductive layers 131. The conductive layer 131 in FIG. 5 is a conductive layer formed by a metal CVD method (performed twice), and the conductive layer 131 in FIG. 6 is a conductive layer formed by a sputtering method (performed twice). Therefore, the conductive layer 131 in FIG. 5 coats the exposed surfaces 211, 212, and 213, whereas the conductive layer 131 in FIG. 6 coats the exposed surface 211 and does not coat the exposed surfaces 212 and 213.

Therefore, in the aperture mask 101 in FIG. 6, as shown with “minus signs” in FIG. 6, electrons which have been shot into the aperture mask 101 by irradiation of a electron beam and which have remained slightly on the surface of the insulating film 112 that constitutes the aperture mask 101, have an adverse effect, from the vicinity of the exposed surface 212 of the insulating film 112 exposed to the side wall surface 203 of the aperture 141, on the track of a subsequent electron beam which passes through the vicinity of the side wall surface 203 of the aperture 141. More specifically, as shown with “an arrow” in FIG. 6, Coulomb repulsive force acts between the remaining electrons near the exposed surface 212 and the subsequent electron beam which passes near the side wall surface 203, so that the track of the subsequent electron beam which passes near the side wall surface 203 is bent.

However, the aperture mask 101 in FIG. 5 is provided with the conductive layer 131, as shown in FIG. 5, on the exposed surface 212 of the insulating film 112 which constitutes the aperture mask 101. Therefore, even in the vicinity of the exposed surface 212, shot-in electrons are removed from the conductive layer 131 to the ground satisfactorily. In this way, the aperture mask 101 in FIG. 5 can further prevent shot-in electrons from having an adverse effect, from the vicinity of the exposed surface 212, on the track of a subsequent electron beam which passes through the vicinity of the side wall surface 203.

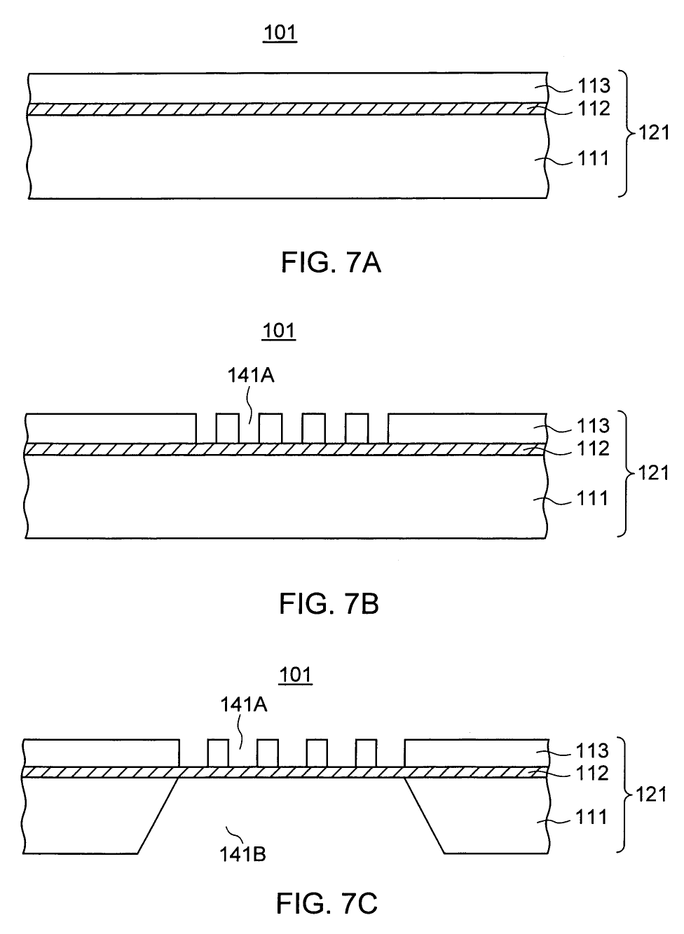

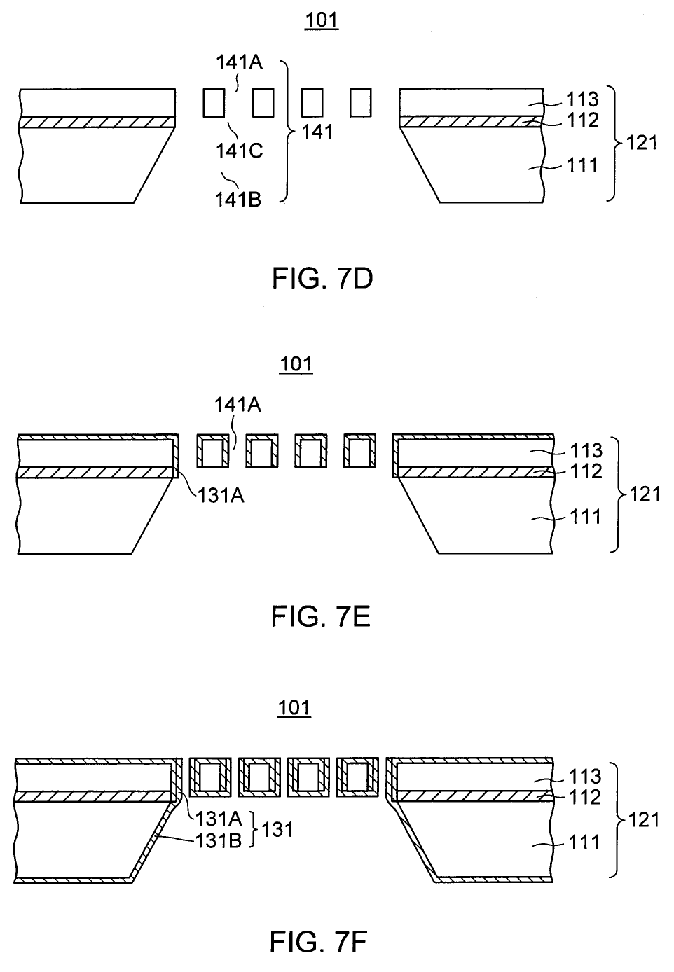

FIGS. 7A to 7F are cross-sectional side views regarding a manufacturing method of the aperture mask 101 in FIG. 1.

First, as shown in FIG. 7A, an SOI substrate 121 including a semiconductor substrate 111, an insulating film 112, and a semiconductor layer 113 is prepared. As the SOI substrate 121, an SOI substrate manufactured by a SIMOX (Separation by Implanted Oxygen) method is used here, but an SOI substrate manufactured by a bonding method may also be used.

The semiconductor substrate 111 is made of Si here, and the thickness of the semiconductor substrate 111 is 0.5 mm here. The semiconductor substrate 111 constitutes the lower surface of the SOI substrate 121.

The insulating film 112 is made of SiO₂ here, and the thickness of the insulating film 112 is 0.5 μm here. The insulating film 112 is used as an etching stop film.

The semiconductor layer 113 is made of Si here, and the thickness of the semiconductor layer 113 is 15 μm here. The semiconductor layer 113 constitutes the upper surface of the SOI substrate 121.

Next, as shown in FIG. 7B, fine openings 141A which constitute an aperture 141 are formed in the semiconductor layer 113 by dry etching. Patterning of the fine opening patterns on a resist for dry etching is performed according to an electron beam lithography scheme here. Trench etching of the semiconductor layer 113 is started from the upper surface of the semiconductor layer 113, and stopped on the upper surface of the insulating film 112 which is an etching stop film.

Next, as shown in FIG. 7C, an opening 141B which constitutes the aperture 141 is formed in the semiconductor substrate 111 by dry etching. Patterning of the opening pattern on a resist for dry etching is performed according to an electron beam lithography scheme here. Back etching of the semiconductor substrate 111 is started from the underside of the semiconductor substrate 111, and stopped on the underside of the insulating film 112 which is an etching stop film.

Next, as shown in FIG. 7D, an opening 141C which constitutes the aperture 141 is formed in the insulating film 112 by dry etching. Thereby, the aperture 141 which penetrates the SOI substrate 121 is completed. That is, the upside fine openings 141A and the underside openings 141B and 141C are penetrated to be the aperture 141.

Next, as shown in FIG. 7E, a first conductive layer 131A made of tungsten is formed, by metal CVD from the upside of the SOI substrate 121. The thickness of the first conductive layer 131A is 0.02 μm here. The upper surface 201 of the SOI substrate 121 and the side wall surface 203 of the aperture 141 are coated with the first conductive layer 131A.

Next, as shown in FIG. 7F, a second conductive layer 131B made of tungsten is formed, by metal CVD from the underside of the SOI substrate 121. The thickness of the second conductive layer 131B is 0.02 μm here. The lower surface 202 of the SOI substrate 121 and the side wall surface 203 of the aperture 141 are coated with the second conductive layer 131B.

The aperture mask 101 in FIG. 1 involves a problem of having a possibility that the conductive layer 131 may be peeled off. However, the problem of “peeling off” can be solved by optimizing conditions of setting the temperature at which the conductive layer 131 is formed and the concentration of the carrier gas.

When the forming temperature of the conductive layer 131 is too high, the conductive layer 131 is contracted substantially between the time of forming the layer and the time after forming the layer, and this causes the “peeling off”. Conversely, when the forming temperature of the conductive layer 131 is too low, the conductive layer 131 is not formed. Therefore, the forming temperature of the conductive layer 131 is preferably slightly higher than the temperature at which the reactant gas activates.

When the concentration of the carrier gas is too high, the film of the conductive layer 131 becomes sparse, that is, the quality of the film of the conductive layer 131 degrades. Conversely, when the concentration of the carrier gas is too low, the forming speed of the conductive layer 131 decreases. Therefore, the concentration of the carrier gas is preferably set in consideration of the balance between the film quality and the forming speed.

It is preferable to use the same material for forming the conductive layer 131A and the conductive layer 131B rather than to use different materials. This is because using different materials causes both layers to be peeled off from each other more easily, for the reason that coefficients of expansion of both layers are different. When different materials are used for forming the conductive layer 131A and the conductive layer 131B, the coefficients of expansion of both layers are preferably as close as possible to each other.

In FIGS. 7A to 7F, with regard to the openings (trenches) 141A, 141B and 141C, they are formed in the order of the openings 141A, 141B and 141C, but they may be formed in the order of openings 141B, 141A and 141C.

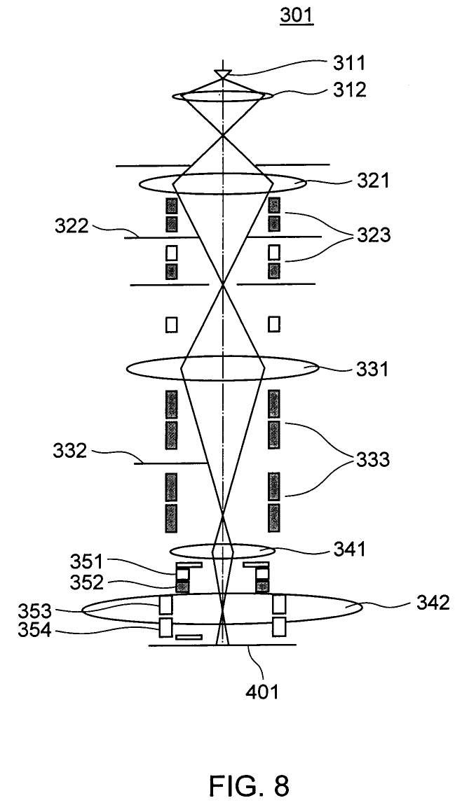

FIG. 8 shows an electron beam lithography apparatus 301. The electron beam lithography apparatus 301 shown in FIG. 8 is equipped with an electron gun 311, a gun lens 312, a condenser lens 321, a first shaping aperture mask 322, a first shaping deflector 323, a projection lens 331, a second shaping aperture mask 332, a second shaping deflector 333, a reducing lens 341, an objective lens 342, a main pre-deflector 351, a sub-deflector 352, a main deflector 353, and a main post-deflector 354. The electron beam lithography apparatus 301 shown in FIG. 8 corresponds to a specific example of the charged beam lithography apparatus.

Each of the first shaping aperture mask 322 and the second shaping aperture mask 332 corresponds to the aperture mask 101 shown in FIG. 1. The first shaping aperture mask 322 is an aperture mask 101 for shaping a rectangular beam, and the second shaping aperture mask 332 is an aperture mask 101 for shaping a patterning beam. Each of the first shaping aperture mask 322 and the second shaping aperture mask 332 is implemented in a condition that the conductive layer 131 shown in FIG. 1 is connected to ground potential. The electron beam lithography apparatus 301 performs electron beam lithography using the first shaping aperture mask 322 and the second shaping aperture mask 332.

The electron beam lithography apparatus 301 in FIG. 8 uses a lowly accelerated electron beam on the order of 1 to 5 keV (here 2 keV). Therefore, the effect of using the aperture mask 101 in FIG. 1 can be said to be large. The electron beam lithography scheme employed by the electron beam lithography apparatus 301 may be a VSB scheme or a CP scheme. An electron beam is shot from the electron gun 311, passes through the first shaping aperture mask 322 and second shaping aperture mask 332 under the track control by the first shaping deflector 323 and the second shaping deflector 333, and is irradiated onto a sample 401 which is a target to be patterned.

As shown above, the embodiment of the present invention relates to charged beam lithography using an aperture mask for the charged beam lithography, and makes it possible to prevent charges shot into the aperture mask from having an adverse effect on the track of a subsequent charged beam which passes through the aperture mask.

What is claimed is:

1. An aperture mask for charged beam lithography, the aperture mask comprising:
a mask substrate having a first semiconductor layer, an insulating film formed on the first semiconductor layer, and a second semiconductor layer formed on the insulating film, and provided with an aperture which penetrates the first semiconductor layer, the insulating film, and the second semiconductor layer; and
a conductive layer which coats a surface of the mask substrate and a side wall surface of the aperture formed in the mask substrate, and which coats an exposed surface of the insulating film exposed to the side wall surface of the aperture.

2. An aperture mask for charged beam lithography, the aperture mask comprising:
a mask substrate having an insulating film, and provided with an aperture which penetrates the insulating film; and
a conductive layer which coats an exposed surface of the insulating film exposed to a side wall surface of the aperture.

3. The aperture mask according to claim 1, wherein the conductive layer coats the surface of one side of the mask substrate, the surface of the other side of the mask substrate, and the side wall surface of the aperture formed in the mask substrate.

4. The aperture mask according to claim 1, wherein the conductive layer is a conductive layer formed by a metal CVD (chemical vapor deposition) method.

5. The aperture mask according to claim 1, wherein the conductive layer is a tungsten film, an iridium film, a platinum film, or a titanium film.

6. The aperture mask according to claim 1, wherein the mask substrate is an SOI substrate manufactured by a SIMOX method or a bonding method.

7. A method of manufacturing an aperture mask for charged beam lithography, the method comprising:
forming, in a mask substrate having a first semiconductor layer, an insulating film formed on the first semiconductor layer, and a second semiconductor layer formed on the insulating film, an aperture which penetrates the first semiconductor layer, the insulating film, and the second semiconductor layer; and
forming a conductive layer which coats a surface of the mask substrate and a side wall surface of the aperture formed in the mask substrate, and which coats an exposed surface of the insulating film exposed to the side wall surface of the aperture.

8. A method of manufacturing an aperture mask for charged beam lithography, the method comprising:
forming, in a mask substrate having an insulating film, an aperture which penetrates the insulating film; and
forming a conductive layer which coats an exposed surface of the insulating film exposed to a side wall surface of the aperture.

9. The method according to claim 7, when forming the conductive layer,
forming, as a first conductive layer which forms the conductive layer, a conductive layer which coats the surface of one side of the mask substrate and the side wall surface of the aperture formed in the mask substrate; and
forming, as a second conductive layer which forms the conductive layer, a conductive layer which coats the surface of the other side of the mask substrate and the side wall surface of the aperture formed in the mask substrate.

10. The method according to claim 7, when forming the conductive layer,
forming the conductive layer by a metal CVD (chemical vapor deposition) method.

11. The method according to claim 7, wherein the conductive layer is a tungsten film, an iridium film, a platinum film, or a titanium film.

12. The method according to claim 7, wherein the mask substrate is an SOI substrate manufactured by a SIMOX method or a bonding method.

13. The method according to claim 7, when forming the aperture, forming the aperture which penetrates the first semiconductor layer, the insulating film, and the second semiconductor layer, by:
forming a trench in the second semiconductor layer using the insulating film as an etching stop film;
then forming a trench in the first semiconductor layer using the insulating film as an etching stop film; and
then forming a trench in the insulating film.

14. The method according to claim 7, when forming the aperture, forming the aperture which penetrates the first semiconductor layer, the insulating film, and the second semiconductor layer, by:
forming a trench in the first semiconductor layer using the insulating film as an etching stop film;
then forming a trench in the second semiconductor layer using the insulating film as an etching stop film; and
then forming a trench in the insulating film.

15. A charged beam lithography apparatus comprising: the aperture mask according to claim 1.

16. A charged beam lithography apparatus comprising: the aperture mask manufactured by the method according to claim 7.

17. The charged beam lithography apparatus according to claim 15, wherein the conductive layer of the aperture mask is connected to ground potential.

18. A charged beam lithography method comprising: performing charged beam lithography using the aperture mask according to claim 1.

19. A charged beam lithography method comprising: performing charged beam lithography using the aperture mask manufactured by the method according to claim 7.

20. The charged beam lithography method according to claim 18, wherein the conductive layer of the aperture mask is connected to ground potential.
